(19) United States
(12) Patent Application Publication
(10) Pub. No.: US 2026/0182048 A1
(43) Pub. Date: Jun. 25, 2026

(54) POLYMER COMPOSITION FOR USE IN SOLAR CELL ASSEMBLIES

(71) Applicant: SABIC GLOBAL TECHNOLOGIES B.V., Bergen op Zoom (NL)

(72) Inventors: Hao LIU, Shanghai (CN); Hongmei ZHOU, Shanghai (CN); Chunfa LI, Shanghai (CN); Jan Nicolaas Eddy DUCHATEAU, Tessenderlo (BE); Maria SOLIMAN, Selfkant (DE); Kai GUO, Shanghai (CN); Pei SUN, Shanghai (CN); Xiaofeng YU, Shanghai (CN); Antonios DOUFAS, Thuwal (SA)

(21) Appl. No.: 19/126,086

(22) PCT Filed: Oct. 9, 2023
(86) PCT No.: PCT/EP2023/077903

§ 371 Date: Apr. 30, 2025

(30) Foreign Application Priority Data
Nov. 2, 2022 (WO) PCT/CN2022/129330
Dec. 2, 2022 (EP) 22211205.4

(51) Int. Cl. H10F 19/80; B29C 48/00; C08J 5/18; C08L 23/16

(52) U.S. Cl. CPC H10F 19/80; B29C 48/0011; C08J 5/18; C08L 23/16; C08L 2205/025; C08L 2666/04; C08L 2666/06

(57) ABSTRACT

A polymer composition comprising:
a) an ethylene-based copolymer;
b) ≥0.1 wt. % and ≤5.0 wt. %, preferably ≥0.1 wt % and ≤1.0 wt %, of a crosslinking agent;
c) ≥0.05 wt. % and ≤5.0 wt. %, preferably ≥0.05 wt % and ≤0.5 wt %, of a coupling agent, preferably a silane coupling agent;
d) ≥0.05 wt. % and ≤5.0 wt. %, preferably ≥0.05 and ≤1.0 wt %, of a co-agent, preferably a phosphate-moiety, isocyanurate-moiety or cyanurate-moiety containing co-agent;
   wherein all wt % are based on the total weight of the polymer composition; and
   wherein the ethylene-based copolymer has a vinyl unsaturation content of ≥6.0 per 10⁵ carbon atoms, preferably ≥7.0 per 10⁵ carbon atoms, when determined in accordance with ASTM D6248-98 (2012).

### CROSS REFERENCE TO RELATED APPLICATIONS

This application is a National Stage application of PCT/EP2023/077903, filed Oct. 9, 2023, which claims the benefit of Application No. PCT/CN2022/129330, filed Nov. 2, 2022 and European Application No. 22211205.4, filed Dec. 2, 2022, both of which are incorporated by reference in their entirety herein.

### BACKGROUND

The present invention relates to a polymer composition suitable for use in solar cell assemblies, in particular in encapsulant systems for the solar cells in such assemblies. In particular, the invention relates to polymer compositions comprising ethylene-based polymers that may be applied in such encapsulant systems.

The increase in use of photovoltaic systems to as element of the mixture of sustainable energy generation solutions, in particular electrical energy generation systems, has given rise to a need for providing high quality, durable, and economically producible solar cell systems. As these systems typically are subject to relatively harsh climate conditions, and exposed to the elements continuously, it is important that an appropriately durable means of protection is provided for the system.

The photovoltaic elements that are the functional part of such solar cell system, in the sense of the actual generation of the electrical energy under exposure to sunlight, typically are relatively fragile elements. In order to ensure that no damage is inflicted onto these elements during manufacturing of the solar cell, the transport, installation, and ultimately its operation, protective measures such as in the form of providing an encapsulation of the cell are commonly employed. This encapsulation needs to provide appropriate adhesion to both the solar cell itself, as well as to any front cover, which may be a glass cover sheet, or a cover sheet of a polymer material, such as a thermoplastic sheet, and back protection or frame member. Furthermore, the encapsulation material needs to provide protection from moisture, air, mechanical shocks, and vibrations, and needs to provide good electrical isolation and thermal creep resistance. Moreover, there are also certain requirements relating to manufacturing of the solar cell systems that need to be dealt with, including the need for easy processing and short curing times.

Such encapsulation materials typically are provided in the form of compositions of thermoplastic materials, which may be applied onto a solar cell as encapsulant, for example in the form of one or more films that jointly encapsulate the solar cell, which subsequently are subjected to certain curing or setting processes. By such curing process, the thermoplastic nature of the composition ceases to be occurring, and crosslinking between polymer molecules takes place. Such cured composition can then comply with the above-stated requirements relating to providing durable protection to the solar cell assembly.

A particularly appropriate class of thermoplastic materials for use in such encapsulation compositions are ethylene-based polymers. Ethylene-based polymers, particularly ethylene-based copolymers, are thermoplastic materials that find abundant and versatile use, and are the world's most ubiquitous thermoplastic materials. Also for use in encapsulant solutions for solar cells, ethylene-based polymers may be a very suitable option, amongst others because of their inert nature.

However, certain needs remain over the ethylene-based polymer compositions that are described in the art. In particular, in manufacturing of the encapsulated solar cells, it is relevant that the curing or crosslinking of the encapsulant composition, which involves a thermal treatment for a certain duration, is such that the initial phase of exposure of the composition to the curing temperature, being the phase wherein the material absorbs the provided heat but remains thermoplastically mouldable, is not too short, so as to allow an appropriate window for the thermoplastic shaping to be performed; where in the other hand, the curing phase itself, being the phase wherein the crosslinking occurs, should be preferably short, to allow economic processing, defined by e.g. desirably short cycle times. Furthermore, the crosslinking degree should be such desirably high.

### SUMMARY

This can now be achieved by application of the polymer composition of the present invention, by a polymer composition comprising:
a) an ethylene-based copolymer;
b) ≥0.1 wt. % and ≤5.0 wt. %, preferably ≥0.1 wt % and ≤1.0 wt %, of a crosslinking agent;
c) ≥0.05 wt. % and ≤5.0 wt. %, preferably ≥0.05 wt % and ≤0.5 wt %, of a coupling agent, preferably a silane coupling agent;
d) ≥0.05 wt. % and ≤5.0 wt. %, preferably ≥0.05 and ≤1.0 wt %, of a co-agent, preferably a phosphate-moiety, isocyanurate-moiety or cyanurate-moiety containing co-agent;
wherein all wt % are based on the total weight of the polymer composition; and
wherein the ethylene-based copolymer has a vinyl unsaturation content of ≥6.0 per 10⁵ carbon atoms, preferably ≥7.0 per 10⁵ carbon atoms, preferably ≥12.0 per 10⁵ carbon atoms, more preferably ≥12.0 and ≤20.0 per 10⁵ carbon atoms, even more preferably ≥12.0 and ≤15.0 per 10⁵ carbon atoms, when determined in accordance with ASTM D6248-98 (2012).

### BRIEF DESCRIPTION OF FIGURES

FIG. 1 shows a cross-section of a photovoltaic module;

FIG. 2 shows a cross-section of a photovoltaic module;

FIG. 3 shows an exploded view of a photovoltaic module;

FIG. 4 shows elution diagrams obtained from HPLC analysis; and

FIG. 5 shows results of torque measurements for examples 1-4.

### DETAILED DESCRIPTION

Such polymer composition allows for a desirably long initial phase in curing, thereby allowing flexibility in thermoplastic moulding, a desirably short curing period, thus reducing cycle time in the production of an encapsulated solar cell assembly, whilst also resulting in a high degree of crosslinking of the encapsulant material.

The ethylene-based polymer may for example have a vinylidene unsaturation content of ≥5.0 per 10⁵ carbon atoms, preferably ≥5.0 and ≤15.0 per 10⁵ carbon atoms, more preferably ≥5.0 and ≤10.0 per 10⁵ carbon atoms, when determined in accordance with ASTM D6248-98 (2012).

For example, the vinyl unsaturation content in the ethylene-based polymer may be greater than its vinylidene unsaturation content, when expressed in unsaturations per 10⁵ carbon atoms, when determined in accordance with ASTM D6248-98 (2012).

In certain embodiments, the ethylene-based copolymer has a vinyl unsaturation content of ≥12.0 and ≤20.0 per 10⁵ carbon atoms, preferably of ≥12.0 and ≤15.0 per 10⁵ carbon atoms, when determined in accordance with ASTM D6248-98 (2012). The use of such ethylene-based copolymer in the polymer composition may contribute to a desired behaviour in curing combined with a desired high degree of crosslinking of the encapsulant material, whilst reducing undesired degradation during the operational life of the final product.

The ethylene-based polymer may for example have a monomodal chemical composition distribution. In the context of the present invention, a monomodal chemical composition distribution is to be understood in that in an HPLC analysis, the elution diagram shows a single peak.

Preferably, the ethylene-based copolymer is a non-polar polymer, such as a polymer that does not contain heteroatoms, in particular oxygen, in its polymeric structure.

It is preferred that the polymer composition comprises ≥90.0 wt % of the ethylene-based copolymer, with regard to the total weight of the polymer composition, preferably ≥95.0 wt %, more preferably ≥98.0 wt %.

The ethylene-based polymer may for example have a density of ≥850 and ≤900 kg/m³, preferably of ≥860 and ≤890 kg/m³, more preferably of ≥865 and ≤885 kg/m³, even more preferably of ≥865 and ≤880 kg/m³, as determined in accordance with ASTM D792 (2008).

The ethylene-based polymer preferably is a copolymer of ethylene and one or more α-olefins selected from 1-butene, 1-hexene, 4-methyl-1-pentene, and 1-octene, particularly preferably 1-octene. The ethylene-based polymer preferably comprises ≥55.0 wt % and ≤80.0 wt %, more preferably ≥60.0 and ≤70.0 wt %, of polymeric moieties derived from ethylene. The ethylene-based polymer preferably comprises ≥20.0 and ≤45.0 wt %, more preferably ≥30.0 and ≤40.0 wt %, of polymeric moieties derived from 1-butene, 1-hexene, 4-methyl-1-pentene, or 1-octene, preferably 1-octene, with regard to the total weight of the ethylene-based polymer.

The ethylene-based polymer my for example have a melt mass-flow rate of ≥2.0 and ≤25.0 g/10 min, preferably of ≥4.0 and ≤20.0 g/10 min, more preferably of ≥4.0 and ≤15.0 g/10 min, as determined in accordance with ASTM D1238 (2013) at 190° C. under a load of 2.16 kg.

The crosslinking agent may for example be selected from 2,5-dimethyl-2,5-di(t-butylperoxy)hexane, 3-di-t-butylperoxide, t-cumylperoxide, 2,5-dimethyl-2,5-di-(t-butylperoxy)hexyne, dicumylperoxide, α,α′-bis(t-butylperoxyisopropyl)benzene, n-butyl-4,4-bis(t-butylperoxy)butane, 2,2-di(t-butylperoxy)butane, 1,1-bis(t-butylperoxy)cyclohexane, t-amylperoxy-2-ethylhexyl carbonate, t-butylperoxy-2-ethylhexyl carbonate, t-butylperoxy benzoate, 1,6-di(t-butylperoxycarbonyl)hexane, and combinations thereof, preferably from dicumylperoxid, t-amylperoxy-2-ethylhexyl carbonate and t-butylperoxy-2-ethylhexyl carbonate, more preferably from t-amylperoxy-2-ethylhexyl carbonate and t-butylperoxy-2-ethylhexyl carbonate.

The coupling agent may for example comprise a silane moiety and at least one alkoxy moiety, preferably wherein the alkoxy moieties comprise 1-5 carbon atoms; preferably the coupling agent comprises three alkoxy moieties comprises each comprising 1-5 carbon atoms; more preferably, the coupling agent further comprises a (meth)acrylate moiety.

For example, the coupling agent may be selected from γ-chloropropyl trimethoxysilane, vinyl trimethoxysilane, vinyl triethoxysilane, vinyl-tris-(p-methoxyphenyl)silane, γ-methacryloxypropyl trimethoxysilane, β-(3,4-ethoxy-cyclohexyl)ethyl trimethoxysilane, γ-glycidoxypropyl trimethoxysilane, γ-mercaptopropyl trimethoxysilane, γ-aminopropyl triethoxysilane, and γ-aminopropyl trimethoxysilane, preferably from vinyl trimethoxysilane and γ-methacryloxypropyl trimethoxysilane, more preferably γ-methacryloxypropyl trimethoxysilane.

The co-agent may for example be a compound according to formula I:

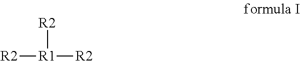

wherein:
   R1 is a trivalent moiety bound to each R2 moiety via a heteroatom, preferably N or O; and
   each R2 is a moiety comprising a terminal vinyl unsaturation, preferably each R2 is a moiety comprising 1-10 carbon atoms, more preferably each R2 is a linear moiety;
preferably wherein each R2 is the same.

More preferably, each R2 is the same and selected from ethenyl, 2-propenyl, 3-butenyl, 4-pentenyl, 5-hexenyl, 6-heptenyl, and 7-octenyl.

Preferably, the compound of formula I is selected from:

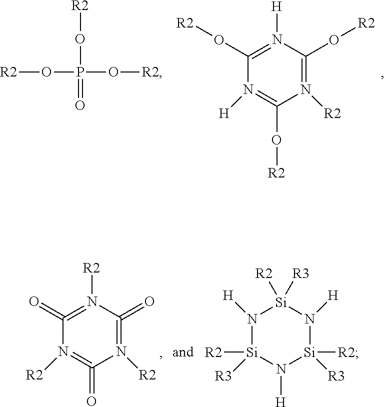

wherein each R3 is a moiety comprising 1-5 carbon atoms, preferably wherein each R3 is a methyl, ethyl, n-propyl, isopropyl, n-butyl or t-butyl moiety, more preferably wherein each R3 is the same.

Particularly preferably, the co-agent is selected from triallyl cyanurate, triallyl phosphate, triallyl isocyanurate, and 2,4,6-trimethyl-2,4,6-trivinyl cyclotrisilazane.

The polymer composition according to the invention may for example be prepared by a process comprising the steps of:
providing to a mixing device, for example to a melt extruder, a set of ingredients comprising
   the ethylene-based polymer;
   ≥0.1 wt. % and ≤5.0 wt. %, preferably ≥0.1 wt % and ≤1.0 wt %, of the crosslinking agent;
   ≥0.05 wt. % and ≤5.0 wt. %, preferably ≥0.05 wt % and ≤0.5 wt %, of the coupling agent, preferably a silane coupling agent; and
   ≥0.05 wt. % and ≤5.0 wt. %, preferably ≥0.05 and ≤1.0 wt %, of the co-agent, preferably a phosphate-moiety, isocyanurate-moiety or cyanurate-moiety containing co-agent;
and
mixing, for example extruding, the set of ingredients at a melt temperature of ≤100° C., preferably ≥80° C. and ≤100° C., to form the polymer composition.

The invention also relates to a film comprising the polymer composition according to the invention. Such film may for example be prepared by a process comprising the steps of:
providing to a melt extruder a set of ingredients comprising
   the ethylene-based polymer;
   ≥0.1 wt. % and ≤5.0 wt. %, preferably ≥0.1 wt % and ≤1.0 wt %, of the crosslinking agent;
   ≥0.05 wt. % and ≤5.0 wt. %, preferably ≥0.05 wt % and ≤0.5 wt %, of the coupling agent, preferably a silane coupling agent; and
   ≥0.05 wt. % and ≤5.0 wt. %, preferably ≥0.05 and ≤1.0 wt %, of the co-agent, preferably a phosphate-moiety, isocyanurate-moiety or cyanurate-moiety containing co-agent;
extruding the set of ingredients at a melt temperature of ≤100° C., preferably ≥80° C. and ≤100° C., to form an extrudate;
and
casting the extrudate at a temperature of ≤100° C. to form the film.

The invention in a further embodiment also relates to an encapsulated solar cell assembly, the assembly comprising a solar cell positioned between positioned between a first and a second sealing layer, wherein each of the first and the second sealing layer comprise or consist of the film of according to the invention, wherein the solar cell is positioned such that the first and the second sealing layer are joined so as to completely encapsulate the solar cell.

Such encapsulated solar cell assembly may be subjected to conditions sufficient to cure the first sealing layer and the second sealing layer, thereby obtaining a cured solar cell assembly. A process for manufacturing of such cured solar cell assembly may for example comprise the steps of:
a) providing a first sealing layer and a second sealing layer, each comprising or consisting of the film of the invention, and a solar cell;
b) assembling the first sealing layer, the solar cell and the second sealing layer in such way that the solar cell is completely encapsulated by the first and the second sealing layer; and
c) curing the encapsulated solar cell assembly under conditions sufficient to cure the first sealing layer and the second sealing layer.

Such conditions that are sufficient to cure the first sealing layer and the second sealing layer preferably are a temperature of between 100° C. and 160° C., preferably between 120° C. and 150° C., for a period of ≥5 and ≤30 min, preferably of ≥10 and ≤20 min.

The invention, in an embodiment, also relates to a photovoltaic module comprising:
a) a front protection member;
b) a back protection member; and
c) the cured solar cell assembly according to the invention, wherein the cured solar cell assembly is positioned between the front protection member and the back protection member.

The front protection member may be a transparent sheet, for example a glass sheet or a polymer sheet, that allows the required radiation to reach the solar cells in the solar cell assembly. The back protection member may be formed by a frame construction for the photovoltaic module.

Furthermore, the invention also relates to the use of the polymer composition according the invention, or the film according to the invention, the reduction of the curing time of a solar cell assembly during the production of a photovoltaic module.

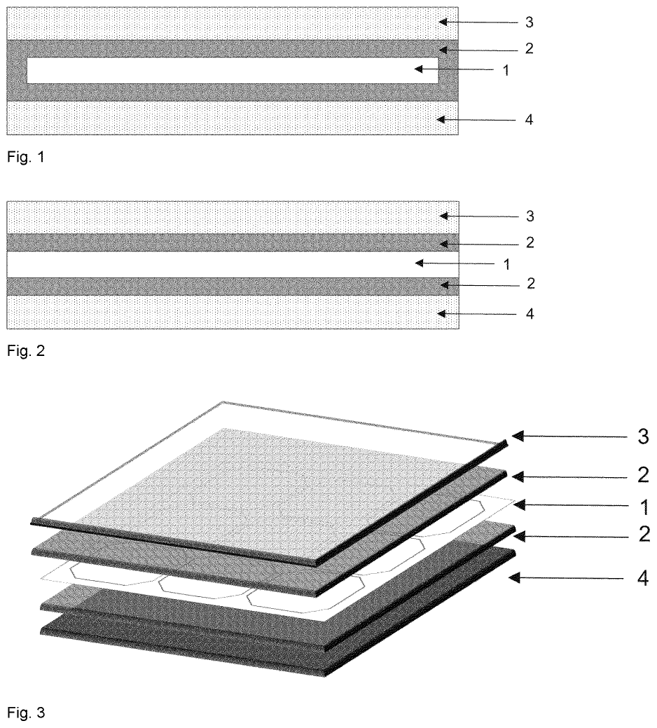

Examples of cross-sections of photovoltaic modules that may comprise the polymer composition according to the invention in its encapsulant layer(s) are provided in FIGS. 1 and 2, wherein (1) indicates the solar cell layer, each (2) an encapsulant layer, (3) the front protection member, and (4) the back protection member. In FIG. 3, an exploded view of such photovoltaic module is provided, wherein each of the references (1)-(4) indicate the same as for FIGS. 1 and 2.

The invention will now be illustrated by the following non-limiting examples.

### Materials

In the examples according to the present invention, the materials as listed in the below table 1 were used to prepare polymer compositions.

TABLE 1
Materials

| | | |
|---|---|---|
| PE1 | Ethylene-based polymer | SABIC Fortify C13075DP |
| PE2 | Ethylene-based polymer | SABIC Fortify C5075DP |
| PE3 | Ethylene-based polymer | Dow Engage PV 8669 |
| PE4 | Ethylene-based polymer | Dow Engage PV 8660 |
| TBEC | Crosslinking agent | t-butylperoxy 2-ethylhexyl carbonate, CAS reg. nr. |
| | | 3443-12-4 |
| TAEC | Crosslinking agent | t-amylperoxy 2-ethylhexyl carbonate, CAS reg. nr. |
| | | 70833-40-8 |
| KH570 | Coupling agent | γ-methacryloxypropyl trimethoxysilane, CAS reg. |
| | | nr. 2530-85-0 |
| TAIC | Co-agent | triallyl isocyanurate, CAS reg. nr. 1025-15-6 |

The ethylene-based polymers PE1-PE4 were analysed to identify material characteristics and properties, the results of which are provided in the table 2 below.

TABLE 2
Properties and characteristics of the ethylene-based polymers

| Property | PE1 | PE2 | PE3 | PE4 |
|---|---|---|---|---|
| Density | 874 | 872 | 869 | 872 |
| MFR2 | 14.6 | 4.9 | 13.7 | 4.6 |
| C8 content | 33.8 | 34.4 | 35.5 | 35.3 |
| M_{w} | 67 | 87 | 70 | 91 |
| Mₙ | 26 | 36 | 26 | 36 |
| M_{w}/Mₙ | 2.6 | 2.4 | 2.7 | 2.5 |
| M_{z} | 120 | 155 | 135 | 175 |
| M_{z}/M_{w} | 1.8 | 1.8 | 1.9 | 1.9 |
| T_{p, m} | 68.3 | 65.6 | 75.7 | 75.9 |
| T_{c} | 49.2 | 48.4 | 53.9 | 53.2 |
| Vinyl content | 14 | 14 | 1 | 1 |
| Vinylidene content | 8 | 8 | 1 | 1 |

### Wherein:

Density is determined in accordance with ASTM D792 (2008), expressed in kg/m³;
MFR2 is the melt mass-flow rate, as determined in accordance with ASTM D1238 (2013) at 190° C. under a load of 2.16 kg, expressed in g/10 min;
C8 content is the wt % of polymeric units derived from 1-octene in the ethylene-based polymers, as determined using ¹³C Nuclear Magnetic Resonance on a Bruker Avance 500 spectrometer equipped with a cryogenically cooled probe head operating at 125° C., whereby the samples were dissolved at 130° C. in C₂D₂Cl₄ containing DBPC as stabiliser;
T_{p,m} is the peak melting temperature as determined using differential scanning calorimetry (DSC) in accordance with ASTM D3418 (2008), expressed in ° C.;
T_{c} is the crystallisation temperature as determined using differential scanning calorimetry (DSC) in accordance with ASTM D3418 (2008), expressed in ° C.;
Mₙ is the number average molecular weight, M_{w} is the weight average molecular weight, and M_{z} is the z-average molecular weight, wherein Mₙ, M_{w}, and M_{z} are each expressed in kg/mol, and determined in accordance with ASTM D6474 (2012);
Vinyl content and vinylidene content is the quantity of each of vinyl unsaturations, and vinylidene unsaturations, expressed in number of unsaturations per 100000 chain carbon atoms, and are determined by ¹³C NMR on a Bruker Avance 500 spectrometer equipped with a cryogenically cooled probe head operating at 125° C., whereby the samples are dissolved at 130° C. in C₂D₂Cl₄ containing DBPC as stabiliser.

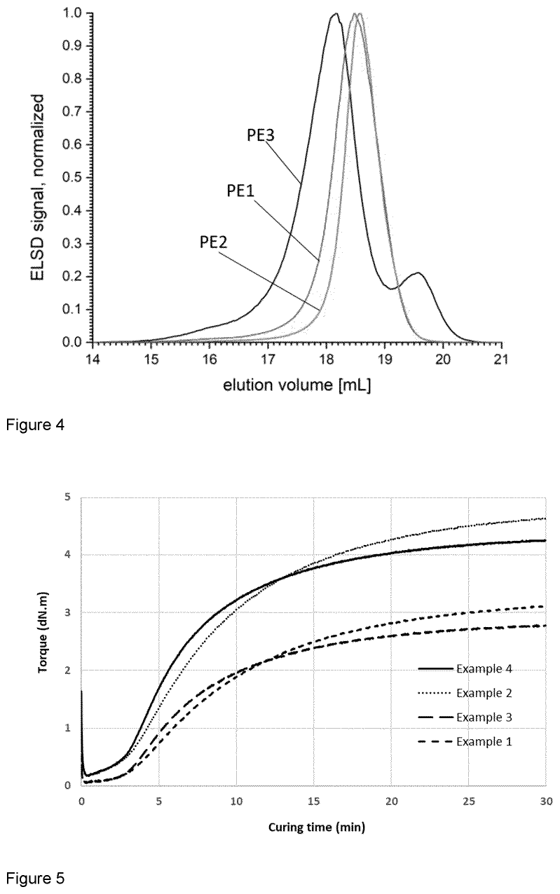

Of PE1-3, elution diagrams obtained from HPLC analysis at 160° C. are shown in FIG. 4. A PolymerChar 2D-LC instrument was used, with a Polymer Labs PL ELS 1000 light scattering detector. The HPLC elution was performed at 160° C., at a flow rate of ≥1 ml/min. Thermofischer Hypercarb columns of particle size 7 μm, of 100 mm length and 4.6 mm internal diameter were used. From this figure, it can be observed that PE1 and PE2 have a monomodal chemical composition distribution, indicated by a single peak in the diagram, whereas PE3 has a bimodal chemical composition distribution, indicated by the presence of two peaks in the diagram.

### Compositions

Using the above-listed materials, the compositions according to the below formulations were produced by mixing the materials in a glass vessel, maintaining the mixtures at room temperature for 12 hours, then compression moulding each of the compositions at 90° C. into a polymer sheet having a thickness of 2-3 mm.

TABLE 3
Compositions

| Example | PE1 | PE2 | PE3 | PE4 | TBEC | TAEC | KH570 | TAIC |
|---|---|---|---|---|---|---|---|---|
| 1 | 50.0 g | | | | 0.375 g | | 0.15 g | 0.25 g |
| 2 | | 50.0 g | | | 0.375 g | | 0.15 g | 0.25 g |
| 3 | | | 50.0 g | | 0.375 g | | 0.15 g | 0.25 g |
| 4 | | | | 50.0 g | 0.375 g | | 0.15 g | 0.25 g |
| 5 | 50.0 g | | | | | 0.375 g | 0.15 g | 0.25 g |
| 6 | | 50.0 g | | | | 0.375 g | 0.15 g | 0.25 g |
| 7 | | | 50.0 g | | | 0.375 g | 0.15 g | 0.25 g |
| 8 | | | | 50.0 g | | 0.375 g | 0.15 g | 0.25 g |

For each of the examples 1-4, curing trials were performed to obtain information on the crosslinking behaviour of the compositions. The compression moulded sheets as obtained via the method above were subjected to curing at 145° C., for a period of 30 min, wherein the curing properties were determined in accordance with ASTM D6601-12. This resulted in torque properties as indicated in the table 4 below:

TABLE 4
Torque properties of compression moulded samples

Torque (dN · m) at curing time

| Example | 1 min | 5 min | 10 min | 15 min | 25 min |
|---|---|---|---|---|---|
| 1 | 0.09 | 0.74 | 1.89 | 2.49 | 3.00 |
| 2 | 0.21 | 1.35 | 3.05 | 3.84 | 4.50 |
| 3 | 0.08 | 0.91 | 1.95 | 2.38 | 2.71 |
| 4 | 0.24 | 1.70 | 3.22 | 3.77 | 4.17 |

In the above table, the examples 1 and 3, and 2 and 4, are particularly relevant to compare to each other, as the properties that typically define these products are similar for these combinations; in examples 1 and 3, the PE1 and PE3 ethylene-based polymers are used, respectively, and in examples 2 and 4, the PE2 and PE4 ethylene-based polymers. PE1 and PE3 have a comparable MFR2 of ca. 14 g/10 min, and a comparable M_{w}, of ca. 70 kg/mol, but differ in their vinyl and vinylidene content. The same applies to PE2 and PE4; similar MFR2 (ca. 5) and M_{w} (ca. 90), but different vinyl and vinylidene content.

The results of the torque measurements for each of the examples 1-4 are presented in FIG. 5.

From the results in table 4, one can observe that at the initiation of curing, reflected by the values at 5 min, the composition 1 has a lower torque value than composition 3; the same applies to composition 2 vs. composition 4. From this, one may derive that the period of thermoplastic behaviour at the onset of curing for the examples according to the invention is longer than for the comparative examples. This is beneficial for the manufacturing process of the encapsulated solar cell assemblies, as it allows for a longer period to have the flexibility to apply the encapsulant to the solar cell.

Further, it can be observed that at a curing time of 10 min, the torque values for the example 1 exceeds that of its comparable example 3, and that of example 2 exceed that of its comparable example 4. From this, one can derive that, using the compositions of examples 1 and 2 one can arrive at the desired degree of curing or crosslinking much faster at a given curing temperature, which is beneficial to the process efficiency in manufacturing of the solar cell assembly; the production time may be reduced by the use of the compositions according to the invention.

This can also be observed by gel content determination of cured samples. Samples of the materials of each of the example 1-4 where, after having been subjected to curing at 145° C. for 15 min, subjected to Soxhlet extraction to determine the gel content of the samples. Values thereof are listed below in the table 5.

TABLE 5
Gel content of cured samples

| Example | 1 | 2 | 3 | 4 | 5 | 6 | 7 | 8 |
|---|---|---|---|---|---|---|---|---|
| Gel content (%) | 81 | 89 | 80 | 87 | 82 | 89 | 77 | 85 |

From table 5, one can observe that for both the set of examples using TBEC as crosslinking agent (1-4), as well as for the set of examples using TAEC as crosslinking agent (5-8), the gel content values for the compositions according to the invention exceed the values of their corresponding comparative compositions.

1. A polymer composition comprising:
a) an ethylene-based copolymer;
b) ≥0.1 wt. % and ≤5.0 wt. % of a crosslinking agent;
c) ≥0.05 wt. % and ≤5.0 wt. % of a coupling agent;
d) ≥0.05 wt. % and ≤5.0 wt. % of a co-agent;
wherein all wt % are based on the total weight of the polymer composition; and
wherein the ethylene-based copolymer has a vinyl unsaturation content of ≥6.0 per 10⁵ carbon atoms, preferably ≥7.0 per 10⁵ carbon atoms, when determined in accordance with ASTM D6248-98 (2012).

2. The polymer composition according to claim 1, wherein the ethylene-based polymer has a vinylidene unsaturation content of ≥5.0 per 10⁵ carbon atoms, when determined in accordance with ASTM D6248-98 (2012).

3. The polymer composition according to claim 1, wherein the ethylene-based polymer has a vinyl unsaturation content that is greater than its vinylidene unsaturation content, when expressed in unsaturations per 10⁵ carbon atoms, when determined in accordance with ASTM D6248-98 (2012).

4. The polymer composition according to claim 1, wherein
the ethylene-based polymer has a monomodal chemical composition distribution; and/or
the ethylene-based copolymer is a non-polar polymer; and/or
the composition comprises ≥90.0 wt % of the ethylene-based copolymer, with regard to the total weight of the polymer composition; and/or
the ethylene-based polymer has a density of ≥850 and ≤900 kg/m³, as determined in accordance with ASTM D792 (2008).

5. The polymer composition according to claim 1, wherein
the ethylene-based polymer is a copolymer of ethylene and one or more α-olefins selected from 1-butene, 1-hexene, 4-methyl-1-pentene, and 1-octene; and/or
the ethylene-based polymer comprises ≥55.0 wt % and ≤80.0 wt % of polymeric moieties derived from ethylene, and/or wherein the ethylene-based polymer comprises ≥20.0 and ≤45.0 wt % of polymeric moieties derived from 1-butene, 1-hexene, 4-methyl-1-pentene, or 1-octene, with regard to the total weight of the ethylene-based polymer; and/or
the ethylene-based polymer has a melt mass-flow rate of ≥2.0 and ≤25.0 g/10 min, as determined in accordance with ASTM D1238 (2013) at 190° C. under a load of 2.16 kg.

6. The polymer composition according to claim 1, wherein the crosslinking agent is selected from 2,5-dimethyl-2,5-di(t-butylperoxy)hexane, 3-di-t-butylperoxide, t-cumylperoxide, 2,5-dimethyl-2,5-di-(t-butylperoxy)hexyne, dicumylperoxide, α,α′-bis(t-butylperoxyisopropyl)benzene, n-butyl-4,4-bis(t-butylperoxy)butane, 2,2-di(t-butylperoxy)butane, 1,1-bis(t-butylperoxy)cyclohexane, t-amylperoxy-2-ethylhexyl carbonate, t-butylperoxy-2-ethylhexyl carbonate, t-butylperoxy benzoate, 1,6-di(t-butylperoxycarbonyl)hexane, and combinations thereof.

7. The polymer composition according to claim 1, wherein the coupling agent comprises a silane moiety and at least one alkoxy moiety.

8. The polymer composition according to claim 1, wherein the coupling agent is selected from γ-chloropropyl trimethoxysilane, vinyl trimethoxysilane, vinyl triethoxysilane, vinyl-tris-(p-methoxyphenyl)silane, γ-methacryloxypropyl trimethoxysilane, β-(3,4-ethoxy-cyclohexyl)ethyl trimethoxysilane, γ-glycidoxypropyl trimethoxysilane, γ-mercaptopropyl trimethoxysilane, γ-aminopropyl triethoxysilane, and γ-aminopropyl trimethoxysilane.

9. The polymer composition according to claim 1, wherein the co-agent is a compound according to formula I: 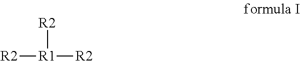
wherein:
R1 is a trivalent moiety bound to each R2 moiety via a heteroatom; and
each R2 is a moiety comprising a terminal vinyl unsaturation.

10. The polymer composition according to claim 9, wherein the compound of formula I is selected from: 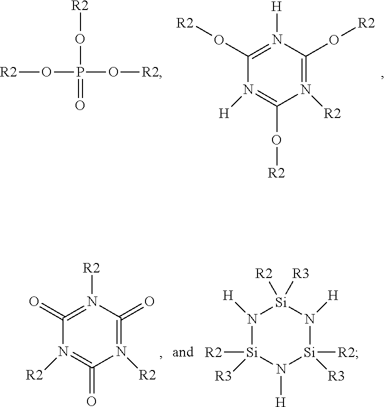
wherein each R3 is a moiety comprising 1-5 carbon atoms.

11. The polymer composition according to claim 1, wherein the co-agent is selected from triallyl cyanurate, triallyl phosphate, triallyl isocyanurate, and 2,4,6-trimethyl-2,4,6-trivinyl cyclotrisilazane.

12. A process for preparation of a polymer composition according to claim 1, comprising the steps of:
providing to a melt extruder a set of ingredients comprising
the ethylene-based polymer;
≥0.1 wt. % and ≤5.0 wt. % of the crosslinking agent;
≥0.05 wt. % and ≤5.0 wt. % of the coupling agent; and
≥0.05 wt. % and ≤5.0 wt. % of the co-agent; and
extruding the set of ingredients at a melt temperature of ≤100° C. to form the polymer composition.

13. A film comprising the polymer composition according to claim 1.

14. A process for preparation of the film of claim 13, comprising the steps of:
providing to a melt extruder a set of ingredients comprising
the ethylene-based polymer;
≥0.1 wt. % and ≤5.0 wt. of the crosslinking agent;
≥0.05 wt. % and ≤5.0 wt. % of the coupling agent; and
≥0.05 wt. % and ≤5.0 wt. % of the co-agent;
extruding the set of ingredients at a melt temperature of ≤100° C. to form an extrudate; and
casting the extrudate at a temperature of ≤100° C. to form the film.

15. A method for reduction of a curing time of a solar cell assembly during production of a photovoltaic module, the method comprising manufacturing the solar cell assembly with the polymer composition according to claim 1.
